(19) United States
(12) Patent Application Publication
(10) Pub. No.: US 2024/0038536 A1
(43) Pub. Date: Feb. 1, 2024

(54) PLASMA PROCESSING APPARATUS, WAFER TO WAFER BONDING SYSTEM AND WAFER TO WAFER BONDING METHOD

(71) Applicant: SAMSUNG ELECTRONICS CO., LTD., SUWON-SI (KR)

(72) Inventors: YONGIN LEE, SUWON-SI (KR); DONGGAP SHIN, SUWON-SI (KR); WOOYOUNG KIM, SUWON-SI (KR); BUMKI MOON, SUWON-SI (KR); JIWON MOON, SUWON-SI (KR); INHWA BAEK, SUWON-SI (KR); SEUNGDAE SEOK, SUWON-SI (KR); SIWOONG WOO, SUWON-SI (KR); SEHOON JANG, SUWON-SI (KR)

(21) Appl. No.: 18/319,850

(22) Filed: May 18, 2023

(30) Foreign Application Priority Data
Jul. 28, 2022 (KR) 10-2022-0093735

(51) Int. Cl. H01L 21/18; H01L 21/02; H01L 21/67

(52) U.S. Cl. CPC H01L 21/187; H01L 21/02076; H01L 21/67167

(57) ABSTRACT

A plasma processing apparatus includes a load lock chamber switchable between an atmospheric pressure state and a vacuum pressure state, and a substrate processing apparatus configured to transfer a substrate to and from the load lock chamber and to perform a plasma process on a surface of the substrate in a plasma chamber under a vacuum atmosphere. The substrate processing apparatus includes a substrate stage disposed within the plasma chamber and configured to support the substrate, a plasma gas supply configured to supply a plasma gas into the plasma chamber, a steam supply configured to supply a water vapor into the plasma chamber, and a plasma generator configured to generate a plasma in the plasma chamber.

### CROSS-REFERENCE TO RELATED APPLICATIONS

This application claims priority under 35 U.S.C. § 119 to Korean Patent Application No. 10-2022-0093735, filed on Jul. 28, 2022 in the Korean Intellectual Property Office (KIPO), the disclosure of which is incorporated by reference herein in its entirety.

### TECHNICAL FIELD

Example embodiments relate to a plasma processing apparatus, a wafer to wafer bonding system and a water to wafer bonding method. More particularly, example embodiments relate to a plasma processing apparatus that performs plasma processing on a wafer surface prior to a wafer bonding process of bonding wafers to each other, a wafer bonding system including the same, and a wafer bonding method using the same.

### DISCUSSION OF RELATED ART

In manufacturing electronic products such as, for example, a CMOS image sensor (CIS), high bandwidth memory (HBM), etc., two wafers may be bonded to each other, which may aid in the miniaturization of semiconductor line width, increase performance through the application of a 3D interconnection structure, and increase a yield rate per wafer. The wafer to wafer bonding process may include, for example, a plasma activation step, a hydration step, a wafer alignment step, a wafer bonding step, an annealing step, etc. A plasma processing apparatus in which the plasma activation step is performed may increase productivity by always maintaining a plasma processing chamber in a vacuum state using a load lock chamber.

### SUMMARY

Example embodiments provide a plasma processing apparatus capable of increasing wafer bonding strength and suppressing change over time.

Example embodiments provide a wafer bonding system including the plasma processing apparatus.

Example embodiments provide a wafer bonding method using the wafer bonding system.

According to example embodiments, a plasma processing apparatus includes a load lock chamber switchable between an atmospheric pressure state and a vacuum pressure state, and a substrate processing apparatus configured to transfer a substrate to and from the load lock chamber and to perform a plasma process on a surface of the substrate in a plasma chamber under vacuum atmosphere. The substrate processing apparatus includes a substrate stage disposed within the plasma chamber and configured to support the substrate, a plasma gas supply configured to supply a plasma gas into the plasma chamber, a steam supply configured to supply a water vapor into the plasma chamber, and a plasma generator configured to generate a plasma in the plasma chamber.

According to example embodiments, a plasma processing apparatus includes a substrate transfer device configured to transfer a substrate under an atmospheric pressure, a substrate processing apparatus configured to perform a plasma process on a surface of the substrate in a plasma chamber under a vacuum atmosphere, a load lock chamber configured to transfer the substrate between the substrate transfer device and the substrate processing apparatus and being switchable between an atmospheric pressure state and a vacuum pressure state, a vacuum transfer module configured to transfer the substrate between the load lock chamber and the substrate processing apparatus under the vacuum atmosphere, and a steam supply configured to supply a water vapor into the plasma chamber.

According to example embodiments, a plasma processing apparatus includes a substrate transfer device configured to transfer wafers from an index module under an atmospheric pressure, a substrate processing apparatus configured to perform a plasma process on a surface of each of the wafers in a plasma chamber under a vacuum atmosphere, a load lock chamber configured to transfer each of the wafers between the substrate transfer device and the substrate processing apparatus and being switchable between an atmospheric pressure state and a vacuum pressure state, a vacuum transfer module configured to transfer each of the wafers between the load lock chamber and the substrate processing apparatus under the vacuum atmosphere, a cleaning apparatus configured to clean the surface of each of the wafers after being plasma processed by the substrate processing apparatus, and a wafer bonding apparatus configured to bond the cleaned wafers to each other. The substrate processing apparatus includes a steam supply configured to supply water vapor into the plasma chamber.

According to example embodiments, in a wafer bonding method, a wafer is loaded into a load lock chamber under atmospheric pressure. The load lock chamber is converted to a vacuum pressure state. Water vapor is supplied into a plasma chamber connected to the load lock chamber. The wafer is loaded into the plasma chamber. Plasma is generated in the plasma chamber to perform a plasma process on the wafer. The wafer is unloaded from the plasma chamber to the load lock chamber.

According to example embodiments, a plasma processing apparatus of a wafer bonding system may include a load lock chamber switchable between an atmospheric pressure state and a vacuum pressure state, and a substrate processing apparatus configured to transfer a substrate to and from the load lock chamber and to perform a plasma process on a surface of the substrate in a plasma chamber under a vacuum atmosphere. The substrate processing apparatus includes a steam supply configured to supply a water vapor into the plasma chamber.

The steam supply may supply the water vapor into the plasma chamber before or when plasma is generated in the plasma chamber. Accordingly, even though the plasma chamber is always kept in a vacuum state, it may be possible to increase and maintain the amount of OH radicals generated by maintaining moisture in the plasma chamber above a certain level. Thus, the bonding strength between the plasma-processed wafers may be increased and the aging change inside the plasma chamber according to the lapse of process time may be suppressed, which may prevent or reduce a decrease in the bonding strength between the wafers over time.

### BRIEF DESCRIPTION OF THE DRAWINGS

The above and other features of the present disclosure will become more apparent by describing in detail example embodiments thereof with reference to the accompanying drawings.

FIG. 1 is a block diagram illustrating a wafer bonding system in accordance with example embodiments.

FIG. 2 is a cross-sectional view taken along the line A-A′ of FIG. 1 illustrating a plasma processing apparatus in FIG. 1 in accordance with example embodiments.

FIG. 3 is a cross-sectional view illustrating a wafer bonding apparatus in FIG. 1 in accordance with example embodiments.

FIG. 4 is a block diagram illustrating a substrate processing apparatus in accordance with example embodiments.

FIG. 5 is a block diagram illustrating a gas supply in FIG. 4 in accordance with example embodiments.

FIG. 6 is a view illustrating the inside of the plasma chamber to which water vapor is supplied by the gas supply of FIG. 5 in accordance with example embodiments.

FIG. 7 is a view illustrating a state in which the water vapor supplied by the gas supply of FIG. 5 is dissociated in a plasma chamber in accordance with example embodiments.

FIG. 8 is a view illustrating a state in which the plasma gas supplied by the gas supply of FIG. 5 and water vapor are dissociated in the plasma chamber in accordance with example embodiments.

FIG. 9 is a flowchart illustrating a wafer bonding method in accordance with example embodiments.

FIG. 10 is a view illustrating the wafer bonding method of FIG. 9 in accordance with example embodiments.

FIG. 11 is a flowchart illustrating detailed operations of a plasma processing operation of FIG. 9 in accordance with example embodiments.

FIGS. 12 and 13 are timing diagrams illustrating a plasma processing operation in accordance with example embodiments.

### DETAILED DESCRIPTION OF EXAMPLE EMBODIMENTS

Example embodiments of the present disclosure will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

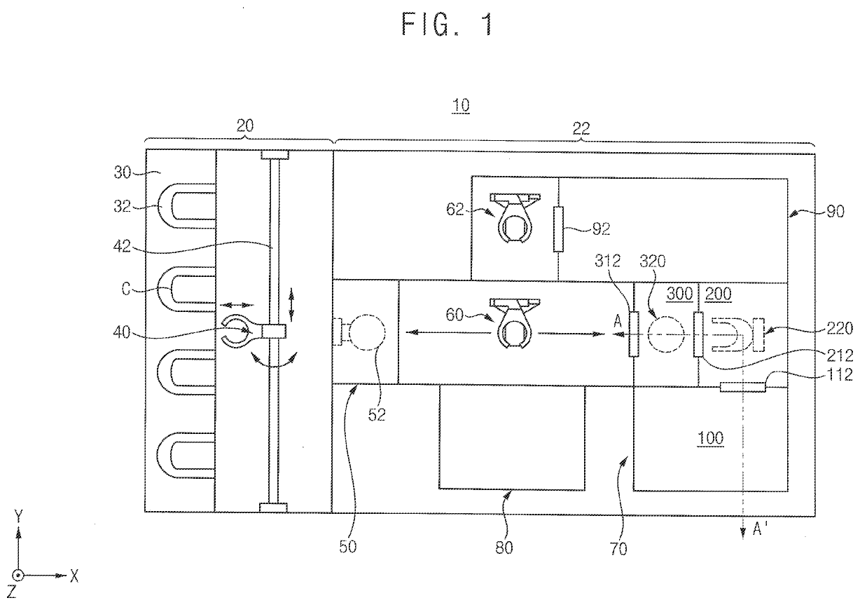

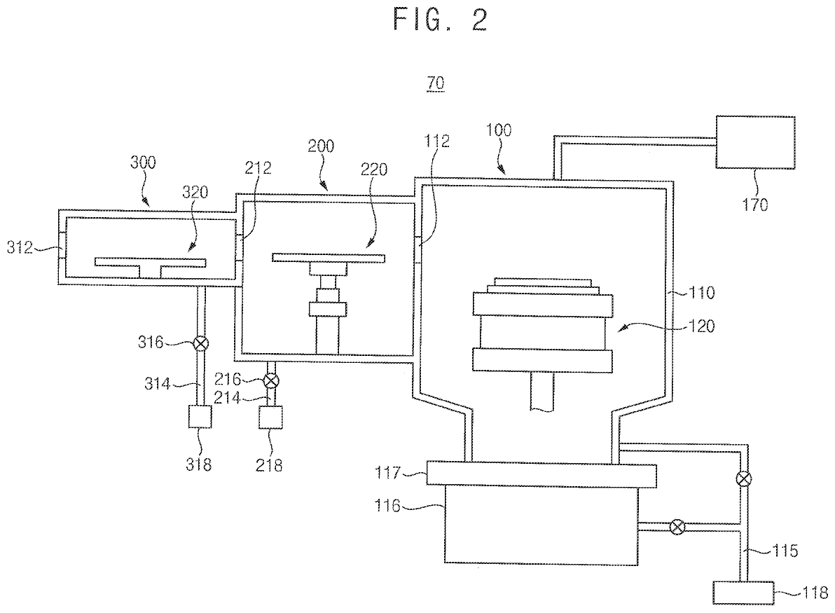

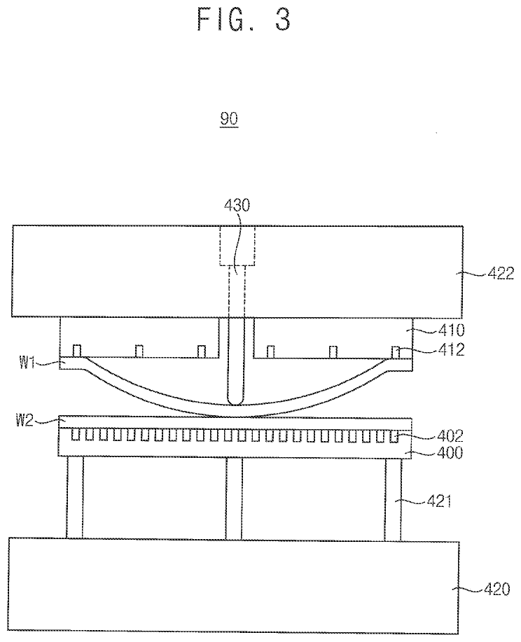

FIG. 1 is a block diagram illustrating a wafer bonding system in accordance with example embodiments. FIG. 2 is a cross-sectional view taken along the line A-A′ of FIG. 1 illustrating a plasma processing apparatus in FIG. 1 according to example embodiments. FIG. 3 is a cross-sectional view illustrating a wafer bonding apparatus in FIG. 1 according to example embodiments.

Referring to FIGS. 1 to 3, a wafer bonding system 10 may include an index module 20 configured to load and unload wafers, and a process module 22 disposed at a side of the index module 20 and configured to bond the wafers to each other. The process module 22 may include a plasma processing apparatus 70, a cleaning apparatus 80 and a wafer bonding apparatus 90. In addition, the process module 22 may further include an alignment apparatus 50. The process module 22 may be an enclosed space having a cuboid shape, and may provide a controlled environment that has a low level of pollutants such as, for example, dust, airborne microbes, aerosol particles, and chemical vapors.

In example embodiments, the index module 20 may include a rectangular cassette stage 30 and an indexer robot 40. The cassette stage 30 may provide a space in which wafers are stored. A plurality of support plates 32 may be disposed along a long side direction (Y direction) of the cassette stage 30. Wafer carriers C (FOUPs), in which a plurality of wafers may be received therein, may be supported on the support plates 32, respectively. The wafer carriers C may also be referred to as carriers C. The wafers received in the carrier C may be transferred into the process module 22 by the indexer robot 40.

For example, three carriers C may be disposed on the cassette stage 30. First and second wafers to be bonded to each other may be received in first and second carriers C respectively, and bonded wafers may be received in a third carrier C. Here, the first wafer may be an upper wafer, and the second wafer may be a lower wafer.

The first wafer may be a wafer in which circuits for an image sensor chip are formed, and the second wafer may be a wafer in which photosensors for the image sensor chip are formed. Alternatively, the first wafer may be a wafer in which circuits for a semiconductor package such as high band memory (HBM) are formed, and the second wafer may be a wafer in which memories for the semiconductor package are formed.

In example embodiments, the alignment apparatus 50 may detect a flat portion P (or notch portion) of the wafer W to align the wafer W. The alignment apparatus 50 may include a base configured to support the wafer W, a rotating portion configured to rotate the base, and a positioning mechanism 52 having a base inverting portion configured to invert the base. The wafer aligned by the alignment apparatus 50 may be transferred to the plasma processing apparatus 70, the cleaning apparatus 80 or the wafer bonding apparatus 90 by transfer robots 60, 62 as substrate transport devices.

According to example embodiments, the alignment apparatus 50 may further include a loading plate configured to temporarily load wafers that are transported by the indexer robot 40 or the transfer robot 60. Additionally, the loading plate may be rotated by an inversion mechanism to invert the wafer adsorbed on the loading plate.

A first transfer robot 60 may move in a transfer region in the process module 22 to transfer the wafer between the alignment apparatus 50, the plasma processing apparatus 70, the cleaning apparatus 80 and the wafer bonding apparatus 90 adjacent to the transfer area. The wafer may be transferred by the first transfer robot 60 under atmospheric pressure. For example, the atmospheric pressure may include atmospheric pressure or a pressure range (±10 kPa) close to the atmospheric pressure. The first transfer robot 60 in the transfer region may serve as at atmospheric transfer module. The first transfer robot 60 may also be referred to herein as a substrate transfer device.

In example embodiments, the plasma processing apparatus 70 may include a substrate processing apparatus 100, a vacuum transfer module 200 and a load lock chamber 300. As will be described below, the plasma processing apparatus 70 may use the load lock chamber 300 to perform plasma processing on a wafer surface while maintaining the plasma chamber 110 of the substrate processing apparatus 100 at a vacuum state at all times.

The load lock chamber 300 may serve as an interfacing chamber between the atmospheric transport module and the vacuum transfer module 200. The load lock chamber 300 may be controlled to selectively allow the wafer to be transferred from the atmospheric transfer module to the vacuum transfer module 200. The load lock chamber 300 may be switchable between an atmospheric pressure state and a vacuum pressure state.

At least one substrate plate 320 for supporting the wafer may be disposed in the load lock chamber 300. The substrate plate 320 may support the wafer. For example, the substrate plate 320 may support a first wafer or a second wafer to be loaded into the plasma chamber 110 from the first transfer robot 60 and may support the first wafer or the second wafer to be unloaded from the plasma chamber 110 to the first transfer robot 60.

As illustrated in FIG. 2, a first vacuum pump 318 may be connected to the load lock chamber 300 by a first exhaust pipe 314. For example, the first vacuum pump 318 may include a dry vacuum pump. When a first gate valve 312 and a second gate valve 212 are closed and a valve 316 installed in the first exhaust pipe 314 is opened, the pressure of the load lock chamber 300 may be reduced to a reduced pressure atmosphere. At this time, the first vacuum pump 318 may operate at all times, and the inside of the load lock chamber 300 may be maintained under the reduced pressure atmosphere through On/Off control of the valve 316. To convert the inside of the load lock chamber 300 into atmospheric pressure, nitrogen or dry air (e.g., clean dry air (CDA)) may be supplied into the load lock chamber 300 to increase the internal pressure to atmospheric pressure and the first gate valve 312 may be opened. Thus, the inside of the load lock chamber 300 may be in communication with the transfer region under atmospheric atmosphere, so that the inside of the load lock chamber 300 becomes an atmospheric atmosphere. Accordingly, the pressure of the load lock chamber 300 may be changeable between the atmospheric pressure and the reduced pressure atmosphere.

A transfer device 220 that transfers the wafer may be disposed in the vacuum transfer module 200. For example, the transfer device 220 may include a transfer arm that is movable in vertical and horizontal directions and rotatable about a vertical axis.

A second vacuum pump 218 may be connected to the vacuum transfer module 200 by a second exhaust pipe 214. For example, the second vacuum pump 218 may include a dry vacuum pump. When the second vacuum pump 218 operates and a valve 216 installed in the second exhaust pipe 214 is opened, the pressure of the vacuum transfer module 200 may be reduced to vacuum atmosphere. When the load lock chamber 300 is under the reduced pressure atmosphere, the second gate valve 212 may be opened. When the plasma chamber 110 is under vacuum atmosphere, a third gate valve 112 may be opened. Accordingly, the transfer device 220 in the vacuum transfer module 200 may transfer the wafer between the load lock chamber 300 and the plasma chamber 110 under vacuum atmosphere. The vacuum transfer module 200 may maintain the vacuum pressure state and is in communication with the load lock chamber 300.

As will be described further below, the substrate processing apparatus 100 may perform plasma processing on a surface of a substrate such as a semiconductor wafer W disposed in the plasma chamber 110 to form a dangling bond on the substrate surface. The wafer W may also be referred to herein as a substrate. A third vacuum pump 118 may be connected to the plasma chamber 110 by a third exhaust pipe 115. For example, the third vacuum pump 118 may include a dry vacuum pump. When the third vacuum pump 118 operates, the pressure of the plasma chamber 110 may be reduced to vacuum atmosphere. Similarly to the vacuum transfer module 200, the plasma chamber 110 may be maintained under the vacuum atmosphere at all times.

In the substrate processing apparatus 100, plasma gas may be excited and converted into plasma under the vacuum atmosphere to form ions and active species. In addition, as these ions and active species are irradiated onto the bonding surface of the wafer, the bonding surface may be plasma-treated and modified.

An internal volume of the load lock chamber 300 may be set to be smaller than an internal volume of the vacuum transfer module 200 or the plasma chamber 110. However, example embodiments are not limited thereto.

Referring again to FIG. 1, the first wafer or the second wafer on which the plasma processing has been performed by the plasma processing apparatus 70 may be loaded into the cleaning apparatus 80 by the first transfer robot 60.

The cleaning apparatus 80 may clean the wafer surface that has been plasma-processed by the plasma processing apparatus 70. The cleaning apparatus 80 may include a nozzle configured to spray deionized (DI) water and a support configured to support and rotate the wafer and may clean the surface of the wafer using the DI water. The DI water may clean the surface of the wafer and may facilitate the bonding of the wafer by allowing —OH groups and water molecules to be well-bonded to the surface of the wafer.

The cleaning apparatus 80 may be disposed adjacent to the plasma processing apparatus 70. Alternatively, the cleaning apparatus 80 may be stacked on the top of the plasma processing apparatus 70. It will be understood that the arrangement of the plasma processing apparatus and the cleaning apparatus is illustrative, and that example embodiments are not limited thereto.

The first wafer or the second wafer rinsed by the cleaning apparatus 80 may be loaded into the wafer bonding apparatus 90 by the first transfer robot 60 and the second transfer robot 62. As illustrated in FIG. 3, the wafer bonding apparatus 90 may include a lower chuck structure and an upper chuck structure. The upper chuck structure may include an upper stage 410 to hold the first wafer W1, and the lower chuck structure may include a lower stage 400 to hold the second wafer W2.

The first wafer W1 may be vacuum suctioned by suction holes 412 of the upper stage 410. The upper stage 410 may be divided into several regions, and the suction holes 412 may be provided in the regions and may be controlled independently of each other. For example, the suction holes may be formed in first to third regions sequentially arranged in a radial direction from the center, respectively. The first region may correspond to a central region of the upper stage 410, the third region may correspond to a peripheral region of the upper stage 410, and the second region may correspond to a middle region between the central region and the peripheral region. The second wafer W2 may be vacuum suctioned by the suction holes 402 of the lower stage 400. Similar to the suction holes of the upper stage, the suction holes of the lower stage 400 may be provided in several regions and may be controlled independently of each other.

The upper stage 410 may be installed fixedly in an upper frame 422. The lower stage 400 may be disposed to face the upper stage 410. The lower stage 400 may be installed to be movable upwardly and downwardly by an elevating rod 421. Accordingly, the second wafer W2 disposed on the lower stage 400 may be moved toward the first wafer W1 disposed on the upper stage 410. In addition, the lower stage 400 may be installed to be movable translationally and rotatationally to adjust its position relative to the upper stage 410.

The wafer bonding apparatus 90 may include a push rod 430 that pressurizes the central region of the first wafer W1. The push rod 430 may be installed to be movable through the upper stage 410. Alternatively, the wafer bonding apparatus 90 may include another push rod for pressing the central region of the second wafer W2 together with or in place of the push rod 430.

When the first and second wafers W1 and W2 are held by the upper stage 410 and the lower stage 400, respectively, a wafer bonding process may be performed.

First, the first wafer W1 may be suctioned on the upper stage 410 with a uniform pressure across the entire surface of the first wafer W1, and the second wafer W2 may be suctioned on the lower stage 400 with a uniform pressure across the entire surface of the second wafer W2.

Then, the push rod 430 may descend to pressurize the central portion of the first wafer W1. Accordingly, the central portion of the first wafer W1 may protrude downward more than the peripheral portion such that the first wafer W1 is convexly curved downward. At this time, the vacuum pressure of the suction holes formed in the first region may be removed, and the vacuum pressure of the suction holes formed in the second and third regions may be maintained such that only the peripheral region of the first wafer W1 may be vacuum suctioned by the suction holes 412 of the upper stage 410.

When the first wafer W1 bends downward to be concave downwardly, the central portion of the first wafer W1 may first contact the second wafer W2 and then gradually join from the central portion to the peripheral region.

Then, the vacuum pressure may be removed from the suction holes 412 of the upper stage 410 to bond the first wafer W1 and the second wafer W2 to each other.

The wafer bonding system 10 may be used to bond a wafer to a wafer, but is not limited thereto. For example, according to example embodiments, the wafer bonding system may perform die-to-wafer bonding or die-to-die bonding.

Hereinafter, the plasma processing apparatus of FIG. 1 will be described in further detail.

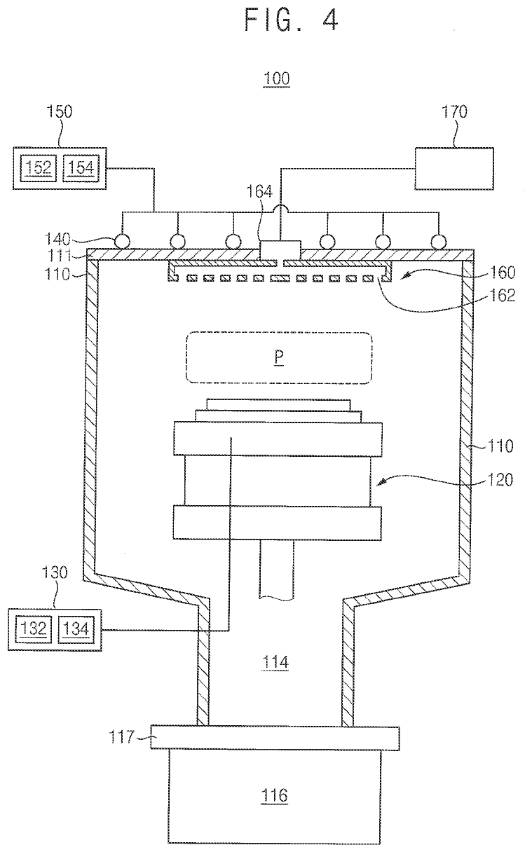

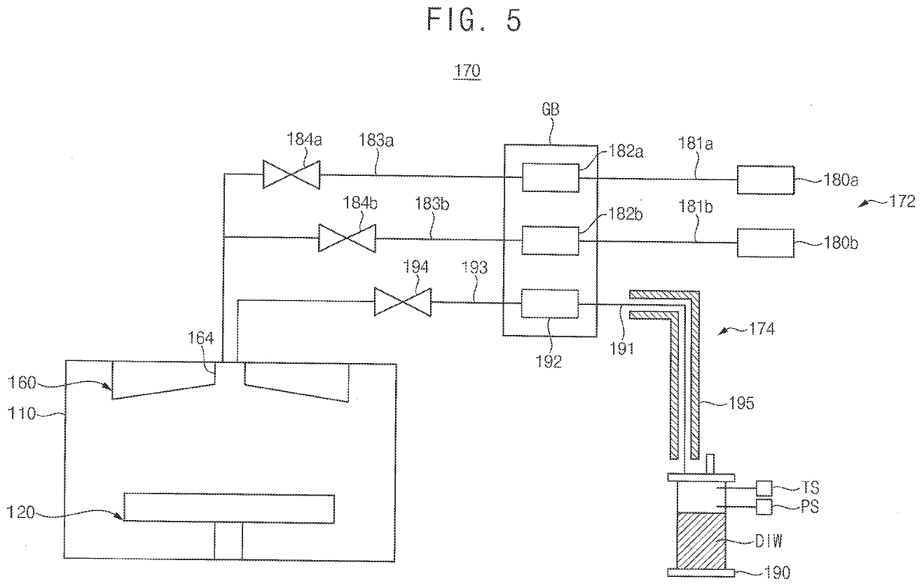

FIG. 4 is a block diagram illustrating a substrate processing apparatus in accordance with example embodiments. FIG. 5 is a block diagram illustrating a gas supply in FIG. 4 in accordance with example embodiments. FIG. 4 is a block diagram illustrating the substrate processing apparatus of FIG. 1 in accordance with example embodiments.

Referring to FIGS. 4 and 5, a substrate processing apparatus 100 may include a plasma chamber 110, a substrate stage 120 having a lower electrode, an upper electrode 140, a shower head 160 and a gas supply 170.

In example embodiments, the substrate processing apparatus 100 may be an apparatus configured to radiate plasma to a surface of a substrate such as a semiconductor wafer W disposed in an inductively coupled plasma (ICP) chamber 110 to form a dangling bond on a substrate surface. However, the plasma generated by the plasma processing apparatus is not limited to the inductively coupled plasma, and may be, for example, a capacitively coupled plasma or a microwave plasma according to example embodiments.

The plasma chamber 110 may provide an enclosed space where a plasma processing process is performed on the wafer W. The plasma chamber 110 may be a cylindrical vacuum chamber. The plasma chamber 110 may include a metal such as, for example, aluminum, stainless steel, etc. The plasma chamber 110 may include a cover 111 that covers an upper end portion of the plasma chamber 110. The cover 111 may airtightly seal the upper end portion of the plasma chamber 110.

A third gate valve 112 (see FIG. 1) may be installed in a sidewall of the plasma chamber 110 to allow the wafer W to enter and exit the plasma chamber 110. The wafer W may be loaded/unloaded onto/from the substrate stage through the third gate valve 112.

An exhaust port 114 may be installed in a bottom portion of the plasma chamber 110. The exhaust port 114 may be connected to a third vacuum pump 118 (see FIG. 2) by a third exhaust pipe 115 (see FIG. 2). An exhaust portion 116 may be connected to the exhaust port 114. The exhaust portion 116 may include an automatic pressure controller (APC) 117 and a turbo molecular pump (TMP), which may be utilized to depressurize the processing space inside the plasma chamber 110 to a desired vacuum level. According to example embodiments, the turbo molecular pump may be omitted, and in this case, only the third vacuum pump 118 may be used. In addition, process by-products and residual process gases generated in the plasma chamber 110 may be discharged through the exhaust port 114.

The substrate stage 120 may support a wafer W within the plasma chamber 110. The substrate stage 120 may include the lower electrode on which the wafer is placed.

The upper electrode 140 may be disposed outside the plasma chamber 110 to face the lower electrode. The upper electrode 140 may be disposed on the cover 111. Alternatively, the upper electrode 140 may be disposed over the shower head 160 or in an upper portion of the plasma chamber.

The upper electrode 140 may include a radio frequency (RF) antenna. The antenna may have a planar coil shape. The cover 111 may include a disc-shaped dielectric window. The dielectric window contains a dielectric material. For example, the dielectric window may include aluminum oxide (Al₂O₃). Power from the antenna may be transferred into the plasma chamber 110 through the dielectric window.

For example, the upper electrode 140 may include spiral or concentric coils. The coil may generate inductively coupled plasma P in the space of the plasma chamber 110. It is to be understood that the number, arrangement, etc. of the coils may be varied according to example embodiments.

In example embodiments, the gas supply 170 may includes a plasma gas supply 172 as a first gas supply configured to supply a plasma gas into the plasma chamber 110, and a steam supply 174 as a second gas supply configured to supply water vapor into the plasma chamber 110. The first gas supply 172 and the second gas supply 174 may be connected to the shower head 160, respectively, and the plasma gas and the water vapor may be supplied into the plasma chamber 110 through the shower head 160.

The plasma gas supply 172 may include a first plasma gas supply for supplying a first plasma gas and a second plasma gas supply for supplying a second plasma gas. For example, the first plasma gas may include oxygen (O₂) gas, and the second plasma gas may include nitrogen (N₂) gas. In addition, the plasma gas supply 172 may further include a third plasma gas supply unit for supplying a third plasma gas such as argon (Ar) gas.

As illustrated in FIG. 5, the first plasma gas supply may include a first plasma gas supply source 180a, first plasma gas supply lines 181a and 183a connected to the first plasma gas supply source 180a to supply the first plasma gas into the plasma chamber 110, and a first flow rate controller 182a for adjusting a supply flow rate of the first plasma gas. These elements may be referred to as first plasma gas supply elements.

The first plasma gas supply source 180a may supply the first plasma gas. For example, the first plasma gas may include oxygen (O₂) gas. The first plasma gas supply lines 181a and 183a may be connected to a gas introduction passage 164 of the shower head 160 in the plasma chamber 110. The first plasma gas from the first plasma gas supply source 180a may be supplied into the plasma chamber 110 through the first plasma gas supply lines 181a and 183a and the shower head 160. The first flow rate controller 182a may control the supply flow rate of the first plasma gas introduced into the plasma chamber 110 through the first plasma gas supply lines 181a and 183a. The first flow rate controller 182a may include a mass flow controller (MFC).

Similarly, the second plasma gas supply may include a second plasma gas supply source 180b, second plasma gas supply lines 181b and 183b connected to the second plasma gas supply source 180b to supply the second plasma gas into the plasma chamber 110, and a second flow rate controller 182b for adjusting a supply flow rate of the second plasma gas. These elements may be referred to as second plasma gas supply elements.

The second plasma gas supply source 180b may supply the second plasma gas. For example, the second plasma gas may include nitrogen (N₂) gas, but is not limited thereto. The second plasma gas supply lines 181b and 183b may be connected to the gas introduction passage 164 of the shower head 160 in the plasma chamber 110. The second plasma gas from the second plasma gas supply source 180b may be supplied into the plasma chamber 110 through the second plasma gas supply lines 181b and 183b and the shower head 160. The second flow rate controller 182b may control the supply flow rate of the second plasma gas introduced into the plasma chamber 110 through the second plasma gas supply lines 181b and 183b. The second flow rate controller 182b may include a mass flow controller (MFC).

According to example embodiments, the gas supply 170 may further include a pressure regulating gas supply configured to supply a pressure regulating gas. The pressure regulating gas supply may include a pressure regulating gas supply source, a pressure regulating gas supply line connected to the pressure regulating gas supply source to supply the pressure regulating gas into the plasma chamber 110, and a flow rate controller for adjusting a supply flow rate of the pressure regulating gas. These elements may be referred to as pressure regulating gas supply elements.

The pressure regulating gas supply source may supply the pressure regulating gas into the plasma chamber 110 to change from a vacuum pressure state to an atmospheric pressure state for maintenance of the chamber. For example, the pressure regulating gas may include a gas such as nitrogen (N2) gas, but is not limited thereto. According to example embodiments, the pressure regulating gas supply line may be connected to an additional supply line installed in a sidewall of the chamber, and not in the shower head 160 in the plasma chamber 110. The pressure regulating gas from the pressure regulating gas supply source may be supplied into the plasma chamber 110 through the pressure regulating gas supply line and the additional supply line.

The steam supply 174 may include a steam supply source 190, steam supply lines 191 and 193 connected to the steam supply source 190 to supply a water vapor into the plasma chamber 110, and a third flow rate controller 192 for adjusting a supply flow rate of the water vapor. These elements may be referred to as steam supply elements.

The steam supply source 190 may supply the water vapor. For example, the steam supply source may be configured to operate in various manners such as via utilization of a by-pass method, a bubbler method and a natural vaporization method. The steam supply lines 191 and 193 may be connected to the gas introduction passage 164 of the shower head 160 in the plasma chamber 110. The water vapor from the steam supply source 190 may be supplied into the plasma chamber 110 through the steam supply lines 191 and 193 and the shower head 160. The third flow rate controller 192 may control the supply flow rate of the water vapor introduced into the plasma chamber 110 through the steam supply lines 191 and 193. The third flow rate controller 192 may include a mass flow controller (MFC).

The first to third flow rate controllers 182a, 182b and 192 may be disposed in a gas box GB. Although it is shown that only the flow rate controllers are installed in the gas box GB, valves, regulators, etc. respectively installed upstream or downstream of the flow rate controllers may be disposed in the gas box GB.

Valves 184a, 184b and 194 may be supply elements for supplying and blocking the plasma gas and the water vapor. As described above, the plasma gas and the water vapor may be supplied into the plasma chamber 110 using the showerhead type. However, example embodiments are not limited thereto. For example, according to example embodiments, the plasma gas and the water vapor may be supplied into the plasma chamber 110 using, for example, a gas injection nozzle type, a flow type, etc.

In example embodiments, the steam supply 174 may further include a heater jacket 195 that surrounds at least a portion of the steam supply line 191. As a result, condensation of the water vapor in the steam supply line 191 may be prevented or reduced. For example, the heater jacket 195 may include a heating pad that surrounds the steam supply line 191.

In addition, the steam supply 174 may further include a temperature sensor TS for detecting temperature of the water vapor in the steam supply source 190, and a pressure sensor PS for detecting pressure of the water vapor in the steam supply source 190.

For example, the pressure in the plasma chamber 110 may be relatively high (several mTorr) (e.g., the temperature may be about 60° C. in an example embodiment), the pressure of the steam supply line 191 may be relatively low (e.g., the temperature may be about 25° C. in an example embodiment), and the pressure in the steam supply source 190 may be relatively low (about 10 Torr) (e.g., the temperature may be about 25° C. in an example embodiment). In this case, when the pressure in the steam supply source 190 drops below about 24 Torr, vaporization may occur and water vapor may be generated from the water DIW. To move the generated water vapor into the plasma chamber 110 without condensation, proper pressure and temperature control of the steam supply source and the steam supply line may be considered.

To prevent or reduce condensation of the water vapor, the temperature of the steam supply line 191 may be maintained above the temperature in the steam supply source 190. The heater jacket 195 may be provided to surround at least a portion of the steam supply line 191 to maintain the temperature of the steam supply line 191 to be higher than the temperature within the steam supply source 190. According to embodiments, the heater jacket may be provided to surround not only the steam supply line 191, but also the entire supply line including the third flow rate controller 192 and the valve, which may increase the efficiency of preventing or reducing condensation of the steam.

A first power supply 150 as a plasma generator may apply plasma source power to the upper electrode 140. For example, the first power supply 150 may include a source RF power source 152 and a source RF matcher 154 as plasma source elements. The source RF power source 152 may generate a radio frequency (RF) signal. The source RF matcher 154 may match impedance of the RF signal generated from the source RF power source 152 using coils to control plasma to be generated.

A second power supply 130 as the plasma generator may apply bias source power to the lower electrode. For example, the second power supply 130 may include a bias RF power source 132 and a bias RF matcher 134 as bias elements. The lower electrode may attract plasma atoms or ions generated in the plasma chamber 110. The bias RF power source 132 may generate a radio frequency (RF) signal. The bias RF power source 132 may match impedance of the bias RF. The bias RF power source 132 and the source RF power source 152 may be synchronized or desynchronized with each other through a tuner of the control unit.

A controller may be connected to the first power supply 150 and the second power supply 130 to control their operations. The controller having a microcomputer and various interface circuits may control an operation of the plasma processing apparatus based on programs and recipe information stored in an external or internal memory.

When radio frequency power having a predetermined frequency is applied to the upper electrode 140, an electromagnetic field induced by the upper electrode 140 may be applied to the plasma gas injected into the plasma chamber 110 to generate plasma P. The bias power may be applied to the lower electrode to attract plasma atoms or ions generated in the plasma chamber 110 toward the lower electrode.

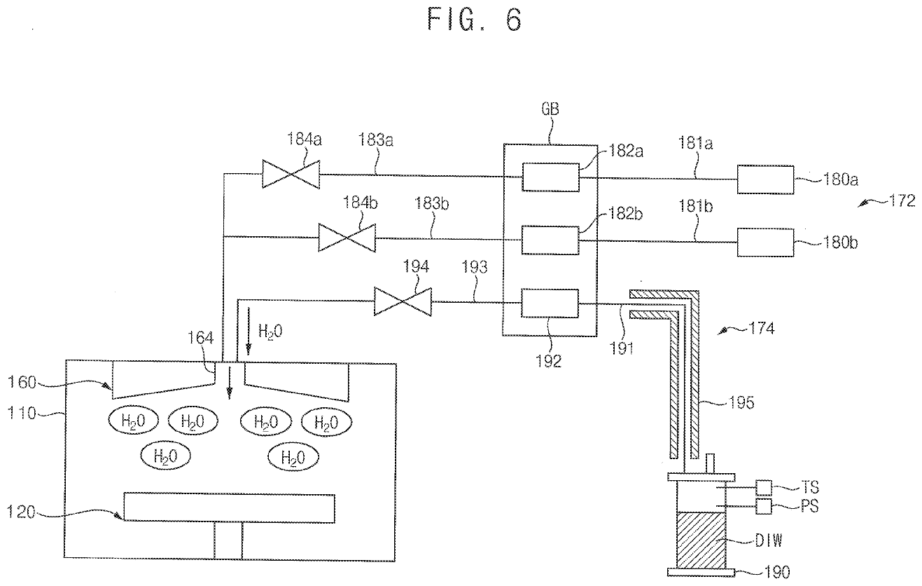

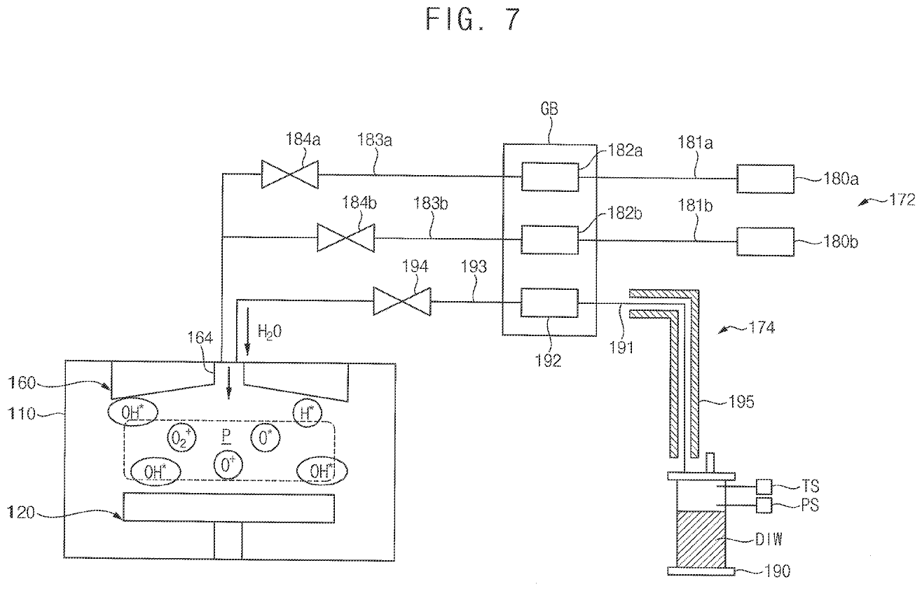

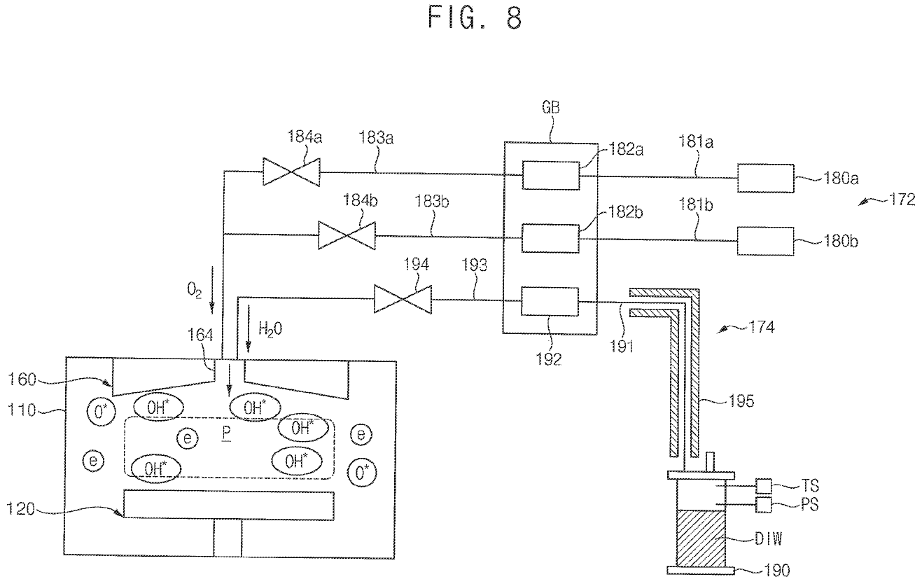

FIG. 6 is a view illustrating the inside of the plasma chamber to which water vapor is supplied by the gas supply of FIG. 5 in accordance with example embodiments. FIG. 7 is a view illustrating a state in which the water vapor supplied by the gas supply of FIG. 5 is dissociated in a plasma chamber in accordance with example embodiments. FIG. 8 is a view illustrating a state in which the plasma gas supplied by the gas supply of FIG. 5 and water vapor are dissociated in the plasma chamber in accordance with example embodiments.

Referring to FIG. 6, the steam supply 174 may supply water vapor into the plasma chamber 110. The steam supply 174 may supply the water vapor into the plasma chamber 110 when the wafer is placed in the load lock chamber 300 or the vacuum transfer module 200. The steam supply 174 may supply the water vapor into the plasma chamber 110 before the wafer W is loaded into the plasma chamber 110 according to example embodiments. The steam supply 174 may supply the water vapor into the plasma chamber 110 before plasma is generated in the plasma chamber 110 according to example embodiments. The steam supply 174 may supply the water vapor and the plasma gas supply 172 may supply the plasma gas simultaneously according to example embodiments.

Referring to FIG. 7, after the water vapor is supplied into the plasma chamber 110, plasma P may be generated in the plasma chamber 110. Due to the dissociation reaction of plasma, the water vapor supplied into the plasma chamber 110 may be dissociated into various ions and radicals such as, for example, H+, H*, H₂+, O+, O₂+, O*, OH+, OH*, etc.

Referring to FIG. 8, the steam supply 174 may supply water vapor at the same time that the plasma gas supply 172 supplies the plasma gas. The steam supply 174 may supply the water vapor into the plasma chamber 110 before or at the same time that plasma is generated in the plasma chamber 110.

Due to the dissociation reaction of plasma, the plasma gas and the water vapor supplied into the plasma chamber 110 may be dissociated into various ions and radicals.

As described above, the plasma chamber 110 may perform plasma processing on wafers in a vacuum state at all times using the load lock chamber 300, which may increase productivity. However, as the plasma chamber 110 always maintains a vacuum state, moisture in the plasma chamber 110 decreases, resulting in a decrease in the amount of OH radicals generated, and thus, the bonding strength between wafers may decrease.

In example embodiments, the steam supply 174 may supply water vapor into the plasma chamber 110. The water vapor may be supplied into the plasma chamber 110 before or at the same time that plasma is generated in the plasma chamber 110. Accordingly, the water vapor may be dissociated due to the dissociation action of the plasma, so that the generation amount of OH radicals may be greatly increased. Thus, even though the vacuum state of the plasma chamber 110 is maintained at all times, the moisture in the plasma chamber 110 may be maintained at a certain level to increase and maintain the amount of OH radicals generated, which may increase and maintain the bonding strength between the wafers.

Hereinafter, a method of bonding wafers using the wafer bonding system of FIG. 1 will be described.

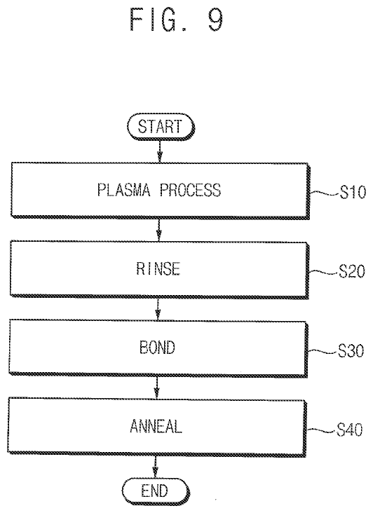

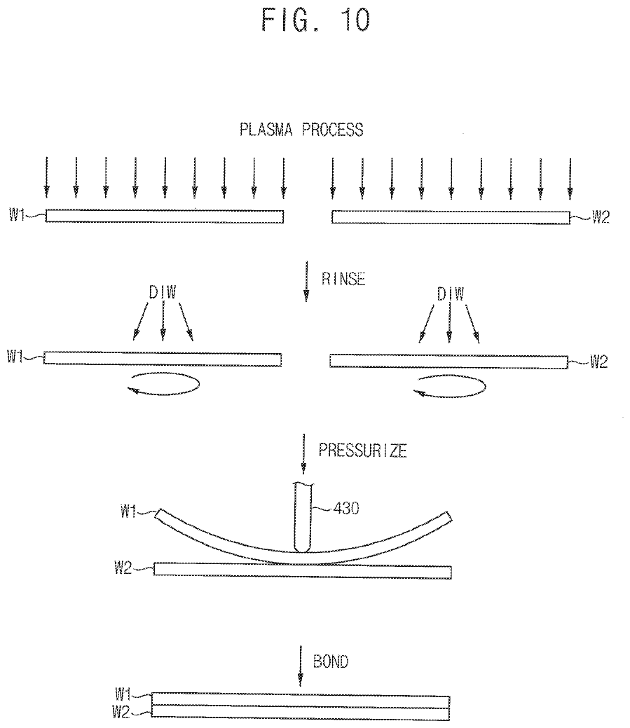

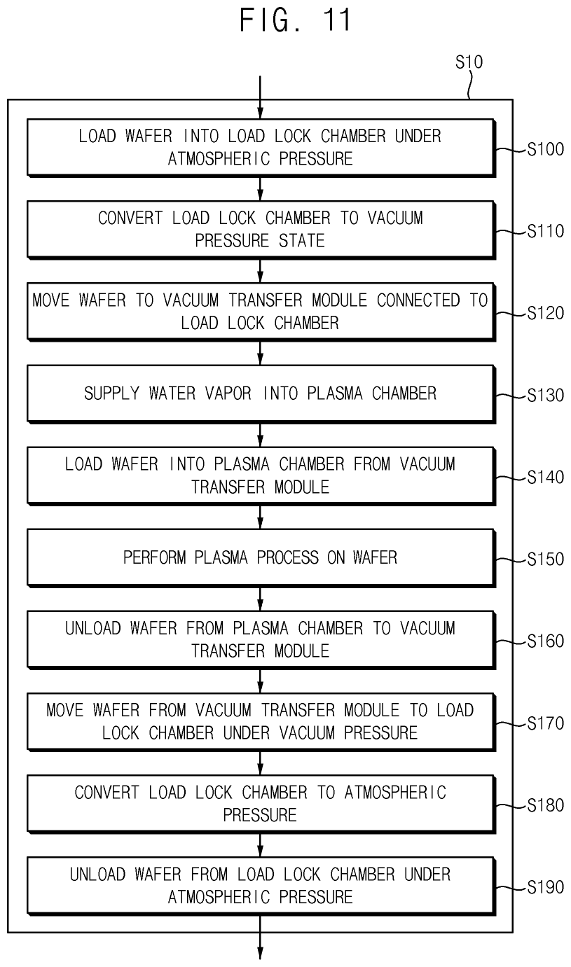

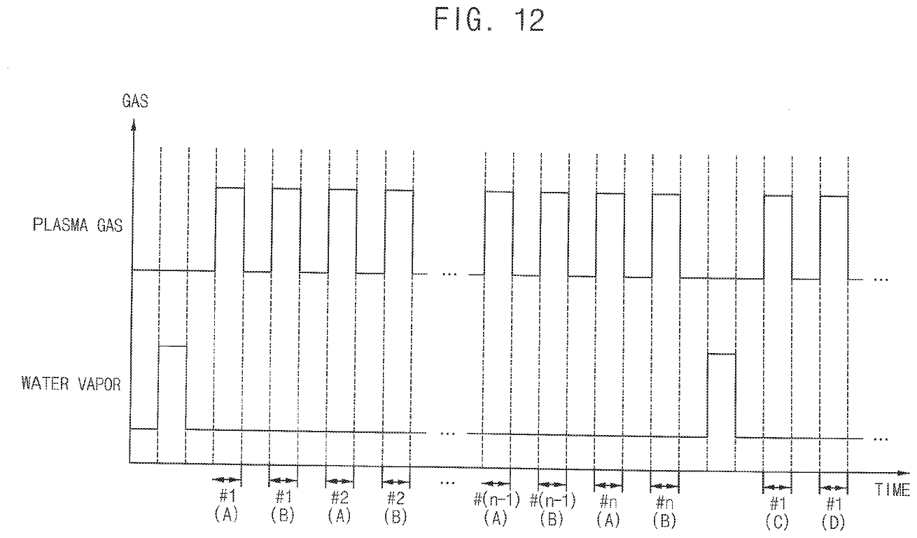

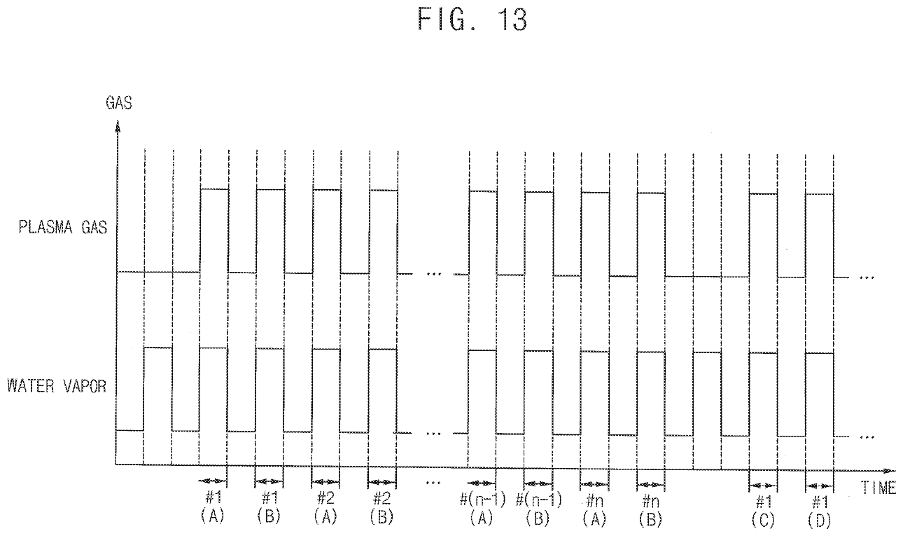

FIG. 9 is a flowchart illustrating a wafer bonding method in accordance with example embodiments. FIG. 10 is a view illustrating the wafer bonding method of FIG. 9 in accordance with example embodiments. FIG. 11 is a flowchart illustrating detailed operations of a plasma processing operation of FIG. 9 in accordance with example embodiments. FIGS. 12 and 13 are timing diagrams illustrating the plasma processing operation in accordance with example embodiments.

Referring to FIGS. 1 to 13, first, plasma processing may be performed on at least one of bonding surfaces of wafers to be bonded to each other (S10).

In example embodiments, the wafer may be loaded into the load lock chamber 300 under atmospheric pressure (S100).

As illustrated in FIGS. 1 and 2, when the wafer is transferred to the front of the load lock chamber 300 under atmospheric pressure by the first transfer robot 60 as the substrate transfer device, the first gate valve 312 may be opened. Then, the wafer may be loaded on the substrate plate 320 in the load lock chamber 300 under atmospheric pressure by the first transfer robot 60. At this time, when another wafer on which plasma processing has been performed is loaded on another substrate plate, the first transfer robot 60 may grip the wafer on another substrate plate and may transfer the wafer from the load lock chamber 300.

Then, the load lock chamber 300 may be converted to a vacuum pressure state (S110). The first gate valve 312 may be closed and the first vacuum pump 318 may be operated so that the load lock chamber 300 is depressurized and converted to a vacuum pressure state.

Then, the wafer may be moved to the vacuum transfer module 200 connected to the load lock chamber 300 (S120), and water vapor may be supplied into the plasma chamber 110 (S130).

The second gate valve 212 may be opened and the transfer device 220 in the vacuum transfer module 200 may move the wafer loaded on the substrate plate 320 into the vacuum transfer module 200.

As illustrated in FIG. 12, before wafers (#1, #2, . . . , #(n−1), #n) of one lot (lot A, lot B) are sequentially plasma-processed in the plasma chamber 110, the steam supply 174 may supply water vapor into the plasma chamber 110. The steam supply 174 may supply the water vapor into the plasma chamber 110 before the wafer is loaded into the plasma chamber 110. After supplying the water vapor into the plasma chamber 110, a first wafer (#1(A)) of lot A, a first wafer (#1(B)) of lot B, a second wafer (#2(A)) of lot A, a second wafer (#2(B)) of lot B, . . . , an n-th wafer (#n(A)) of lot A and an n-th wafer (#n(B)) of lot B may be sequentially plasma-processed. After plasma processing of the wafers of lots A and B is performed, the steam supply 174 may supply water vapor into the plasma chamber 110. The plasma-processed wafers of lot A and lot B may be bonded to each other in a subsequent bonding process.

For example, one lot may include 25 wafers. However, example embodiments are not limited thereto. For example, it will be understood that the water vapor may be supplied before plasma processing of various quantities of wafers according to lot units and batch units according to example embodiments. Although FIG. 12 illustrates lots A, B, C and D, example embodiments are not limited thereto.

Then, the wafer may be loaded into the plasma chamber 110 from the vacuum transfer module 200 (S140).

The third gate valve 112 may be opened, and the transfer device 220 in the vacuum transfer module 200 may transfer the wafer loaded on the substrate plate 320 into the plasma chamber 110 of the substrate processing apparatus 100.

Then, the third gate valve 112 may be closed, and plasma processing may be performed on the wafer in the plasma chamber 110 (S150).

As illustrated in FIGS. 4 and 5, the plasma gas supply 172 may introduce a plasma gas into the plasma chamber 110 through spray holes 162 of the shower head 160, and the pressure in the plasma chamber 110 may be adjusted to a high vacuum pressure by the exhaust portion 116. Then, plasma power may be applied to the upper electrode 140 to generate plasma P in the plasma chamber 110 and bias power may be applied to the lower electrode to perform plasma process.

As illustrated in FIG. 13, before wafers (#1, #2, . . . , #(n−1), #n) of one lot (lot A, lot B) are sequentially plasma-processed in the plasma chamber 110 and when the wafers are plasma-processed, the steam supply 174 may supply water vapor into the plasma chamber 110. For example, the steam supply 174 may supply the water vapor into the plasma chamber 110 whenever all wafers are plasma processed. At the same time that the plasma gas supply 172 supplies the plasma gas, the steam supply 174 may supply the water vapor. Alternatively, the steam supply 174 may supply the water vapor into the plasma chamber 110 whenever plasma processing of a plurality of wafers (e.g., 2 wafers, 4 wafers, 6 wafers, etc.) is performed.

The steam supply 174 may supply the water vapor into the plasma chamber 110 when the wafer is in the load lock chamber 300. In addition, the steam supply 174 may supply the water vapor into the plasma chamber 110 when plasma processing of a specific wafer (e.g., wafer #2) is performed. At the same time that the plasma gas supply 172 supplies the plasma gas, the steam supply 174 may supply the water vapor.

Then, the wafer may be unloaded from the plasma chamber 110 to the vacuum transfer module 200 (S160), the wafer may be moved from the vacuum transfer module 200 to the load lock chamber 300 under vacuum pressure (S170), the load lock chamber 300 may be converted to atmospheric pressure (S180), and the wafer may be unloaded from the load lock chamber 300 under atmospheric pressure (S190).

When the surface treatment of the wafer is completed, the second and third gate valves 212 and 112 may be opened, and the transfer device 220 may take the wafer out of the plasma chamber 110 and transfer the wafer onto the substrate plate 320 of the load lock chamber 300. Then, after the second and third gate valves 212 and 112 are closed, nitrogen gas or dry air may be supplied into the load lock chamber 300 to make the internal pressure equal to atmospheric pressure. Accordingly, the inside atmosphere of the load lock chamber 300 may be switched from a reduced pressure state to an atmospheric pressure state. Then, the first gate valve 312 may be opened, and the transfer robot 60 may take the plasma-processed wafer off of the substrate plate 320 of the load lock chamber 300 and may transfer to the plasma-processed wafer to the cleaning apparatus 80 in which a following process is performed.

Then, the surface of the plasma-treated wafer may be rinsed/cleaned (S20), and the cleaned wafers may be bonded to each other (S30). Then, the bonded wafers may be annealed (S40).

In example embodiments, the cleaning apparatus 80 may include a nozzle that sprays DI water (DIW) and a support portion capable of supporting and rotating the wafer to clean the wafer surface using the DI water (DIW). The DI water (DIW) may not only clean the surface of the wafer W, but also facilitate the bonding of the wafer W by allowing -OH groups and water molecules to be well-bonded to the surface of the wafer W.

Then, after loading the cleaned wafers W1 and W2 into the wafer bonding apparatus 90, the wafers W1 and W2 may be suctioned to be held on the upper stage 410 and the lower stage 400 respectively. The first wafer W1 may be vacuum suctioned by the suction holes 412 formed in the upper stage 410. The second wafer W2 may be vacuum suctioned by the suction holes 402 formed in the lower stage 400.

Then, the push rod 430 may descend and pressurize the central portion of the first wafer W1 to convexly bend the first wafer W1 downward. At this time, only the peripheral region of the first wafer W1 may be vacuum-suctioned by the suction holes 412 formed in the upper stage 410.

In a state in which the first wafer W1 is convexly deformed downward, the upper stage 410 may be lowered to bring the first wafer W1 into contact with the second wafer W2. At this time, the central portion of the first wafer W1 may initially contact the second wafer W2 and then gradually join from the central portion to the peripheral region.

Then, the first wafer W1 and the second wafer W2 may be bonded to each other by removing the vacuum pressure from the suction holes 412 of the upper stage 410.

Then, the bonded wafers W1 and W2 may be thermally treated by the annealing apparatus.

The above-described wafer to wafer bonding system and wafer to wafer bonding method may be used to manufacture, for example, semiconductor packages or image sensors including logic devices and memory devices. For example, the semiconductor packages may include volatile memory devices such as DRAM devices and SRAM devices, or non-volatile memory devices such as flash memory devices, PRAM devices, MRAM devices, ReRAM devices, etc. The image sensor may include a CMOS image sensor.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A plasma processing apparatus, comprising:
a load lock chamber switchable between an atmospheric pressure state and a vacuum pressure state; and
a substrate processing apparatus configured to transfer a substrate to and from the load lock chamber, and to perform a plasma process on a surface of the substrate in a plasma chamber under a vacuum atmosphere,
wherein the substrate processing apparatus comprises:
a substrate stage disposed within the plasma chamber and configured to support the substrate;
a plasma gas supply configured to supply a plasma gas into the plasma chamber;
a steam supply configured to supply a water vapor into the plasma chamber; and
a plasma generator configured to generate a plasma in the plasma chamber.

2. The plasma processing apparatus of claim 1, wherein the steam supply supplies the water vapor into the plasma chamber before the substrate is loaded into the plasma chamber.

3. The plasma processing apparatus of claim 1, wherein the steam supply supplies the water vapor into the plasma chamber before the plasma is generated in the plasma chamber.

4. The plasma processing apparatus of claim 1, wherein the steam supply supplies the water vapor and the plasma gas supply supplies the plasma gas simultaneously.

5. The plasma processing apparatus of claim 1, wherein the steam supply comprises:
a steam supply source configured to supply the water vapor;
a steam supply line connected to the steam supply source and configured to supply the water vapor into the plasma chamber; and
a flow rate controller configured to adjust a supply flow rate of the water vapor.

6. The plasma processing apparatus of claim 5, wherein the steam supply further comprises:
a heater jacket that surrounds at least a portion of the steam supply line.

7. The plasma processing apparatus of claim 5, wherein the steam supply further comprises:
a temperature sensor that detects a temperature of the water vapor in the steam supply source; and
a pressure sensor that detects a pressure of the water vapor in the steam supply source.

8. The plasma processing apparatus of claim 1, further comprising:
a vacuum transfer module configured to transfer the substrate between the load lock chamber and the substrate processing apparatus under the vacuum atmosphere.

9. The plasma processing apparatus of claim 8, wherein the vacuum transfer module comprises a transfer arm configured to transfer the substrate.

10. The plasma processing apparatus of claim 8, wherein the vacuum transfer module maintains the vacuum pressure state and is in communication with the load lock chamber.

11. A plasma processing apparatus, comprising:
a substrate transfer device configured to transfer a substrate under an atmospheric pressure;
a substrate processing apparatus configured to perform a plasma process on a surface of the substrate in a plasma chamber under a vacuum atmosphere;
a load lock chamber configured to transfer the substrate between the substrate transfer device and the substrate processing apparatus, the load lock chamber being switchable between an atmospheric pressure state and a vacuum pressure state;
a vacuum transfer module configured to transfer the substrate between the load lock chamber and the substrate processing apparatus under the vacuum atmosphere; and
a steam supply configured to supply a water vapor into the plasma chamber.

12. The plasma processing apparatus of claim 11, wherein when the load lock chamber is in the vacuum pressure state, the vacuum transfer module is depressurized to a vacuum state and is in communication with the load lock chamber.

13. The plasma processing apparatus of claim 11, wherein the steam supply supplies the water vapor into the plasma chamber before the substrate is loaded into the plasma chamber.

14. The plasma processing apparatus of claim 11, wherein the steam supply supplies the water vapor into the plasma chamber before plasma is generated in the plasma chamber.

15. The plasma processing apparatus of claim 11, wherein the steam supply supplies the water vapor into the plasma chamber when plasma is generated in the plasma chamber.

16. The plasma processing apparatus of claim 11, wherein the steam supply comprises:
a steam supply source configured to supply the water vapor;
a steam supply line connected to the steam supply source and configured to supply the water vapor into the plasma chamber; and
a flow rate controller configured to adjust a supply flow rate of the water vapor.

17. The plasma processing apparatus of claim 16, wherein the steam supply further comprises:
a heater jacket that surrounds at least a portion of the steam supply line.

18. The plasma processing apparatus of claim 16, wherein the steam supply further comprises:
a temperature sensor that detects a temperature of the water vapor in the steam supply source; and
a pressure sensor that detects a pressure of the water vapor in the steam supply source.

19. The plasma processing apparatus of claim 11, further comprising:
a cleaning apparatus configured to clean the surface of the substrate after the substrate has been plasma processed by the substrate processing apparatus.

20. A plasma processing apparatus, comprising:
a substrate transfer device configured to transfer wafers from an index module under an atmospheric pressure;
a substrate processing apparatus configured to perform a plasma process on a surface of each of the wafers in a plasma chamber under a vacuum atmosphere;
a load lock chamber configured to transfer each of the wafers between the substrate transfer device and the substrate processing apparatus, the load lock chamber being switchable between an atmospheric pressure state and a vacuum pressure state;
a vacuum transfer module configured to transfer each of the wafers between the load lock chamber and the substrate processing apparatus under the vacuum atmosphere;
a cleaning apparatus configured to clean the surface of each of the wafers after being plasma processed by the substrate processing apparatus; and
a wafer bonding apparatus configured to bond the cleaned wafers to each other,
wherein the substrate processing apparatus comprises a steam supply configured to supply water vapor into the plasma chamber.
